(19) United States
(12) Patent Application Publication
(10) Pub. No.: US 2011/0260293 A1
(43) Pub. Date: Oct. 27, 2011

(54) VARIABLE CAPACITANCE DEVICE AND METHOD OF FABRICATING THE SAME

(76) Inventor: Kaoru Narita, Tokyo (JP)

(21) Appl. No.: 13/063,229

(22) PCT Filed: Jul. 22, 2009
(86) PCT No.: PCT/JP2009/063079

§ 371 Date: Mar. 10, 2011

(30) Foreign Application Priority Data
Oct. 31, 2008 (JP) 2008-282263

(51) Int. Cl. H01L 29/93; H01L 21/20; B82Y 99/00; B82Y 40/00

(52) U.S. Cl. 257/595; 438/379; 977/742; 257/E29.344; 257/E21.09

(57) ABSTRACT

Provided is a variable capacitance device including a nanomaterial layer made of a plurality of kinds of nanomaterials having characteristics different from each other, a first conductive layer electrically connected to at least a part of the nanomaterial layer, and a second conductive layer facing the nanomaterial layer and the first conductive layer through an insulating film.

### TECHNICAL FIELD

The present invention relates to a variable capacitance device using materials other than silicon and a method of fabricating the same.

### BACKGROUND ART

Variable capacitance devices (varactors) are devices that can change the capacitance value depending on external voltage. For example, they are used for a voltage-controlled oscillator, a phase-locked circuit, a frequency synthesizer, and a circuit of an antenna for frequency control or the like, and they are components necessary for information communication devices such as a portable terminal.

On the other hand, currently, technical development is actively being conducted in which electronic components (wires and transistors) are formed on a plastic substrate or the like by printing processes. Techniques for variable capacitance devices are also expected to produce the devices by coating and printing processes.

Current variable capacitance devices are fabricated chiefly using silicon semiconductors. For fabrication processes, lithography, high temperature processes, and a vacuum atmosphere are necessary, and the devices cannot be fabricated by coating and printing processes.

Thus, in order to fabricate variable capacitance devices by coating and printing processes, proposed are such variable capacitance devices that use materials other than silicon as shown below.

For example, Patent Document 1 describes a variable capacitance device in which a nanowire is formed in an NPN type and a voltage is applied between the P- and N-types to vary the thickness of a depleted layer for changing capacitance values.

In addition, Non-Patent Document 1 describes a varactor based on MEMS and a technique which carbon nanotubes are vertically arranged and a voltage is applied therebetween for varying capacitances due to displacement caused by electrostatic forces. Moreover, Non-Patent Document 2 describes a capacitor utilizing carbon nanotubes, and Non-Patent Document 3 describes a variable capacitance device using pentacene that is an organic material.

Furthermore, Patent Document 2 describes a capacitor which at least one of two electrodes facing each other is formed in a carbon nanotube structure in which a plurality of carbon nanotubes have functional groups bonded with each other and which they form a mesh structure having the functional groups cross-linked with each other by chemical bonding.

### RELATED ART DOCUMENTS

### Patent Documents

Patent Document 1: U.S. Pat. No. 7,115,971

Patent Document 2: JP2005-123428A

### Non-Patent Documents

Non-Patent Document 1: “Variable capacitance mechanisms in carbon nanotubes”, Journal of Applied Physics 101, 036111, (2007)

Non-Patent Document 2: “Nanoscale capacitors based on metal-insulator-carbon nanotube-metal structures”, Applied Physics Letter 87, 263103, (2005)

Non-Patent Document 3: “Spatial Extent of Wave Functions of Gate-Induced Hole Carriers in Pentacene Field-Effect Devices as Investigated by Electron Spin Resonance”, Physical Review Letters 97, 256603 (2006)

### SUMMARY OF THE INVENTION

Problems that the Invention is to Solve

However, the structures shown in Patent Document 1, Non-Patent Document 1, and Non-Patent Document 2 are all need to be fabricated by controlling the position and orientation of each of individual nanowires or carbon nanotubes, giving rise to the problem that fabrication of such structures is not easy. In particular, fabrication of such structures is difficult as regards the processes of coating and printing.

Moreover, the structure shown in Non-Patent Document 3 uses pentacene for a material, giving rise to a problem in which the structure is not suited for coating and printing processes because its typical fabrication method is vapor deposition. Furthermore, the variable capacitance device using pentacene has a low operating frequency at a frequency of about 100 Hz, in which there is the problem in that the variable capacitance device cannot be used for high frequency circuits in megahertz to gigahertz bands for main applications of variable capacitance devices.

Furthermore, the variable capacitance device described in Patent Document 2 cannot increase or control changes in the capacitance value for the bias.

The present invention has been made in view of the above-mentioned problems.

The object is to provide a variable capacitance device enabling an increase in or control over changes in the capacitance value for the bias.

### Means for Slving the Problems

In order to achieve the above-mentioned object, a variable capacitance device according to the present invention includes:

a nanomaterial layer made of a plurality of various kinds of nanomaterials having characteristics different from each other;

a first conductive layer electrically connected to at least a part of the nanomaterial layer;

and a second conductive layer facing the nanomaterial layer and the first conductive layer through an insulating film.

In addition, in order to achieve the above-mentioned object, a method of fabricating a variable capacitance device according to the present invention includes:

a first ink applying step of applying ink containing a metal nanoparticle over a substrate;

a first conductive layer forming step of performing firing processing to precipitate a metal for forming a first conductive layer;

an insulating film forming step of forming an insulating film in at least a part of an area on the first conductive layer formed in the first conductive layer forming step;

a nanomaterial layer forming step of applying ink containing a nanomaterial over the insulating film formed in the insulating film forming step and forming a nanomaterial layer made of a plurality of various kinds of nanomaterials having characteristics different from each other;

a second ink applying step of applying ink containing a metal nanoparticle over at least a part of an area on the nanomaterial layer formed in the nanomaterial layer forming step;

and a second conductive layer forming step of performing firing processing to precipitate a metal for forming a second conductive layer electrically connected to the nanomaterial layer.

### Effect of the Invention

According to the present invention, a variable capacitance device includes a plurality of various kinds of nanomaterials having characteristics different from each other. Accordingly, it is possible to increase and control changes in the capacitance value for the bias.

### BRIEF DESCRIPTION OF THE DRAWINGS

FIG. 1a is a plan view depicting a variable capacitance device according to a first embodiment of the present invention;

FIG. 1b is a cross sectional view along line A-A′ of FIG. 1a;

FIG. 2a is a diagram illustrative of a method of fabricating the variable capacitance device shown in FIGS. 1a and 1b;

FIG. 2b is a diagram illustrative of the method of fabricating the variable capacitance device shown in FIGS. 1a and 1b;

FIG. 2c is a diagram illustrative of the method of fabricating the variable capacitance device shown in FIGS. 1a and 1b;

FIG. 2d is a diagram illustrative of the method of fabricating the variable capacitance device shown in FIGS. 1a and 1b;

FIG. 3 is a diagram of data plotted in the measurement of capacitance values based on an AC voltage of 1 MHz, while a DC bias is being applied between a first electrode and a second electrode of the variable capacitance device shown in FIGS. 1a and 1b;

FIG. 4 is a cross sectional view depicting a variable capacitance device according to a second embodiment of the present invention;

FIG. 5 is a cross sectional view depicting a variable capacitance device according to a third embodiment of the present invention;

FIG. 6a is a diagram depicting an equivalent circuit where there is one kind of CNT layer;

FIG. 6b is a diagram depicting an equivalent circuit of the variable capacitance device shown in FIG. 5;

FIG. 7 is a diagram depicting changes in the capacitance value where a bias is applied to the circuits shown in FIGS. 6a and 6b;

FIG. 8 is a diagram depicting frequency response of capacitances where a bias is constant;

FIG. 9 is a cross sectional view depicting a variable capacitance device according to a fourth embodiment of the present invention;

FIG. 10a is a diagram depicting an equivalent circuit where there is one kind of CNT layer;

FIG. 10b is a diagram depicting an equivalent circuit of the variable capacitance device shown in FIG. 9;

FIG. 11 is a diagram depicting changes in the capacitance value where a bias is applied to the circuits shown in FIGS. 10a and 10b; and

FIG. 12 is a cross sectional view depicting a variable capacitance device according to a fifth embodiment of the present invention.

### MODE FOR CARRYING OUT THE INVENTION

In the following, embodiments of the present invention will be described with reference to the drawings.

### First Embodiment

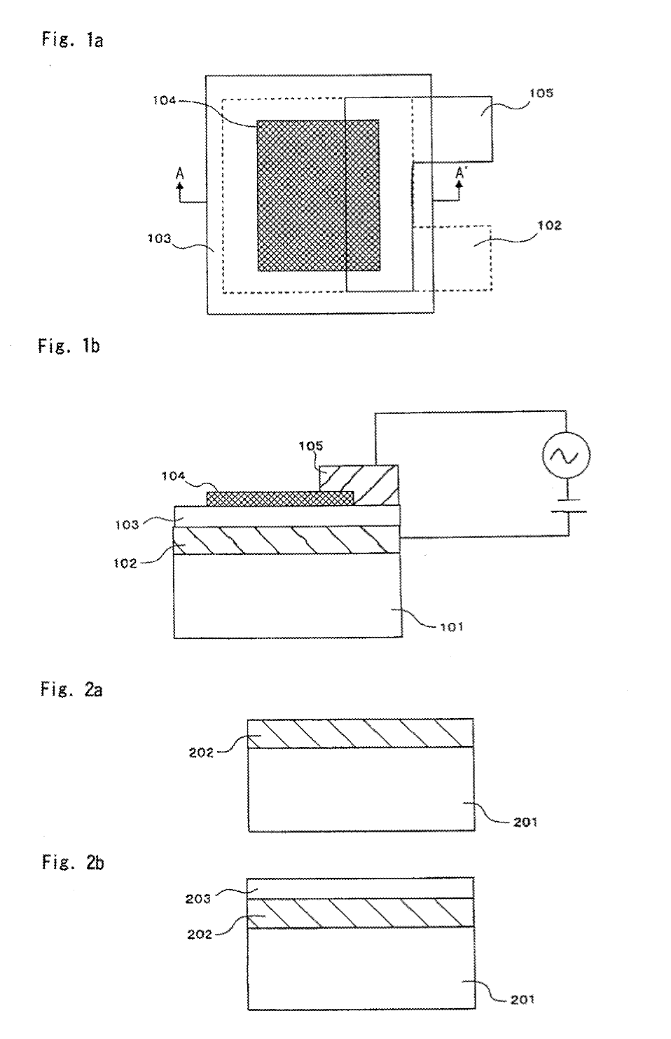

FIG. 1a is a plan view depicting a variable capacitance device according to a first embodiment of the present invention, and FIG. 1b is a cross sectional view along line A-A′ of FIG. 1a.

As shown in FIG. 1b, the variable capacitance device according to this embodiment includes polyimide substrate 101, first electrode 102 that is a first conductive layer made of a metal nanomaterial or the like, polyimide insulating film 103, carbon nanotube (CNT) layer 104 that is a nanomaterial layer, and second electrode 105 that is a second conductive layer made of a metal nanomaterial or the like.

On polyimide substrate 101, first electrode 102 made of nanosilver is provided, CNT layer 104 is provided through polyimide insulating film 103 having a thickness of about 500 nm, and second electrode 105 similarly made of nanosilver is electrically connected to CNT layer 104.

CNT layer 104 is a mat layer in which a large number of single-layer CNTs are connected in a mesh and the single-layer CNTs has an average diameter of about 1 nm and an average length of about 0.5 μm. One-third of CNT layer 104 is formed of metallic CNTs, and two-thirds are formed of semiconducting CNTs.

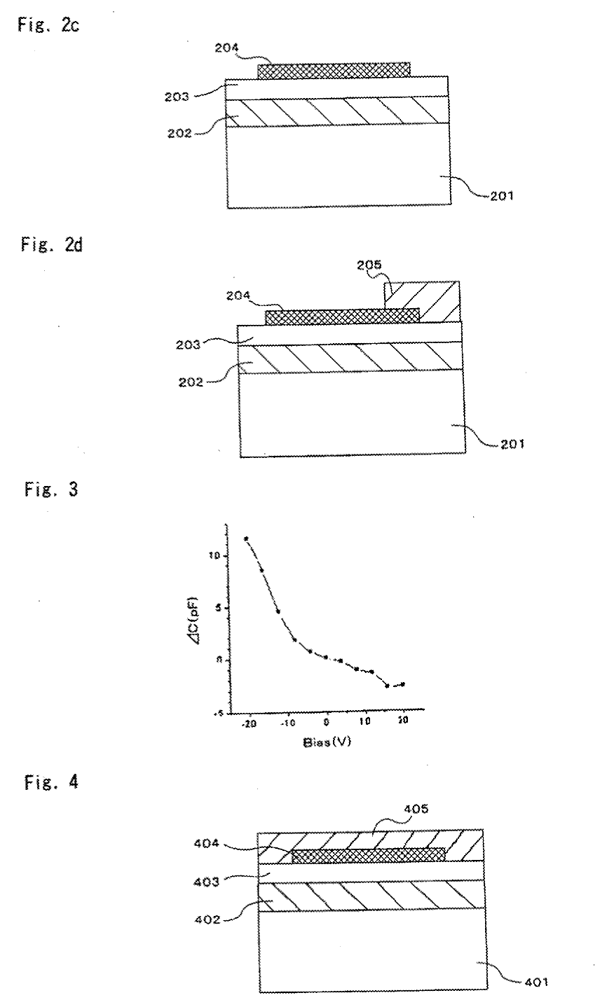

FIGS. 2a to 2d are diagrams illustrative of a method of fabricating the variable capacitance device shown in FIGS. 1a and 1b.

First, as shown in FIG. 2a, nanosilver ink is applied over polyimide substrate 201, and subjected to firing processing at a temperature of 200° C. for silver separation, and first electrode 202 is formed.

Subsequently, as shown in FIG. 2b, an organic solvent containing polyimide is applied over first electrode 202 for firing processing at a temperature of 200° C., and polyimide insulating film 203 having a thickness of about 500 nm is formed.

Subsequently, as shown in FIG. 2c, a solution having CNTs dispersed in an organic solvent is applied over polyimide insulating film 203, and CNT layer 204 is formed by vaporizing the solvent.

Subsequently, as shown in FIG. 2d, nanosilver ink is applied, and subjected to firing processing at a temperature of 200° C. for silver separation, and second electrode 205 connected to CNT layer 204 is formed.

FIG. 3 is a diagram of data plotted in the measurement of capacitance values based on an AC voltage of 1 MHz, while a DC bias is being applied between first electrode 102 and second electrode 105 of the variable capacitance device shown in FIGS. 1a and 1b. In addition, in FIG. 3, the horizontal axis indicates the DC bias, and the vertical axis indicates changes in the capacitance value.

As shown in FIG. 3, it is possible that the variable capacitance device according to this embodiment changes capacitance values based on the bias to be applied. Moreover, because one-third of CNT layer 104 is metallic CNTs, the layer resistance of the CNT layer is reduced, so that it is possible for the variable capacitance device to operate at high frequencies.

### Second Embodiment

FIG. 4 is a cross sectional view depicting a variable capacitance device according to a second embodiment of the present invention.

As shown in FIG. 4, the variable capacitance device according to this embodiment includes polyimide substrate 401, first electrode 402, polyimide insulating film 403, CNT layer 404, and second electrode 405, as similar to those shown in FIGS. 1a and 1b.

One difference from the variable capacitance device shown in FIGS. 1a and 1b is that second electrode 405 entirely covers CNT layer 404. According to this configuration, although changes in the capacitance are relatively small, the resistance of CNT layer 404 is reduced, and it is possible for the variable capacitance device to operate at much higher frequencies.

### Third Embodiment

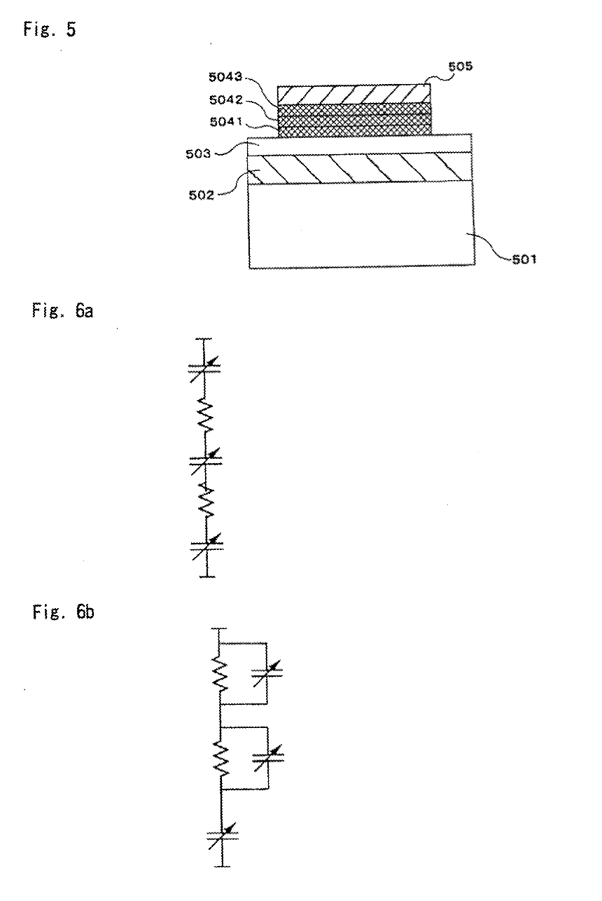

FIG. 5 is a cross sectional view depicting a variable capacitance device according to a third embodiment of the present invention.

As shown in FIG. 5, the variable capacitance device according to this embodiment includes polyimide substrate 501, first electrode 502, polyimide insulating film 503, first CNT layer 5041, second CNT layer 5042, third CNT layer 5043, and second electrode 505.

In this embodiment, the CNT layer is formed of a multi-layer film in a three-layer structure having first CNT layer 5041, second CNT layer 5042, and third CNT layer 5043.

First CNT layer 5041 is formed only of semiconducting CNTs, second CNT layer 5042 is formed to include one-third of metallic CNTs, and third CNT layer 5043 is formed to include two-thirds of metallic CNTs.

As described above, forming the CNT layer in the three-layer structure provides 100% semiconducting first CNT layer 5041 where an electric field is strong and where the insulating film is nearest, allowing the absolute value of the capacitance value and changes in the capacitance value to be at the maximum. In addition, the existence of second CNT layer 5042 and third CNT layer 5043 causes the resistance of the CNT layer to be low, so that it is possible for the variable capacitance device to operate at much higher frequencies.

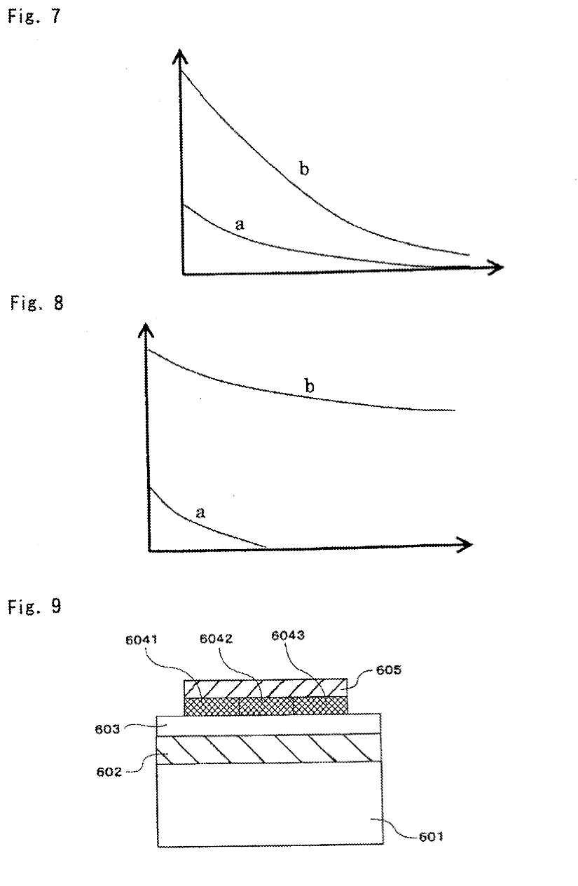

FIG. 6a is a diagram depicting an equivalent circuit where there is one kind of CNT layer, and FIG. 6b is a diagram depicting an equivalent circuit of the variable capacitance device shown in FIG. 5. Moreover, FIG. 7 is a diagram depicting changes in the capacitance value where a bias is applied to the circuits shown in FIGS. 6a and 6b. Furthermore, curve a shown in FIG. 7 indicates changes in the capacitance value where there is one kind of CNT layer, and curve b shown in FIG. 7 indicates changes in the capacitance value where the CNT layer has three different layers.

As shown in FIG. 7, in the case in which the CNT layer is formed in the three-layer structure as in this embodiment, the amount of changes in the capacitance value for the variation in the bias becomes greater as well as the absolute value of the capacitance value becomes larger, as compared with the case in which there is one kind of CNT layer.

In addition, FIG. 8 is a diagram depicting the frequency response of capacitances where a bias is constant. Moreover, curve a shown in FIG. 8 indicates changes in the capacitance value where there is one kind of CNT layer, and curve b shown in FIG. 8 indicates changes in the capacitance value where the CNT layer has three layers.

As shown in FIG. 8, in the case in which there is one kind of CNT layer, the capacitance value quickly reduces as the frequency increases. In contrast to this, in the structure in which the CNT layer has three layers and in which metallic CNTs are more included as closer to the upper electrode, parasitic resistance is reduced, so that a reduction in the capacitance value is small even when the frequency is increased.

As described above, increases in the absolute value of the capacitance value and in the amount of changes in the capacitance value for the variation in the bias provide the effect that widens the application range of the variable capacitance device for allowing application to a wide variety of circuits. In addition, the readiness of the variable capacitance device for higher frequencies also provides the effect that the variable capacitance device is applicable to much faster circuits.

### Fourth Embodiment

FIG. 9 is a cross sectional view depicting a variable capacitance device according to a fourth embodiment of the present invention.

As shown in FIG. 9, the variable capacitance device according to this embodiment includes polyimide substrate 601, first electrode 602, polyimide insulating film 603, first CNT layer 6041, second CNT layer 6042, third CNT layer 6043, and second electrode 605.

In this embodiment, the CNT layer includes three CNT layers, first CNT layer 6041, second CNT layer 6042, and third CNT layer 6043, which are provided in the areas on the same face.

First CNT layer 6041 is formed of single semiconducting layer CNTs having an average diameter of about 1 nm, second CNT layer 6042 is formed of that having an average diameter of about 1.5 nm, and third CNT layer 6043 is formed of that having an average diameter of about 2 nm.

Now, semiconducting CNTs have the characteristic in which the band gap becomes narrower as the diameter becomes larger. In the case of the variable capacitance device, the bias value (threshold) for changing the capacitance value becomes low. More specifically, first CNT layer 6041 has the highest threshold, then second CNT layer 6042, and third CNT layer 6043 has the lowest threshold.

Accordingly, in the structure according to this embodiment, such a characteristic is obtained in which variable capacitances having different thresholds are connected side by side, so that it is possible to change the capacitance value in a much wider bias range. As described above, multiple areas of the CNT layers having different characteristics are provided to control the characteristics between the bias and the capacitance.

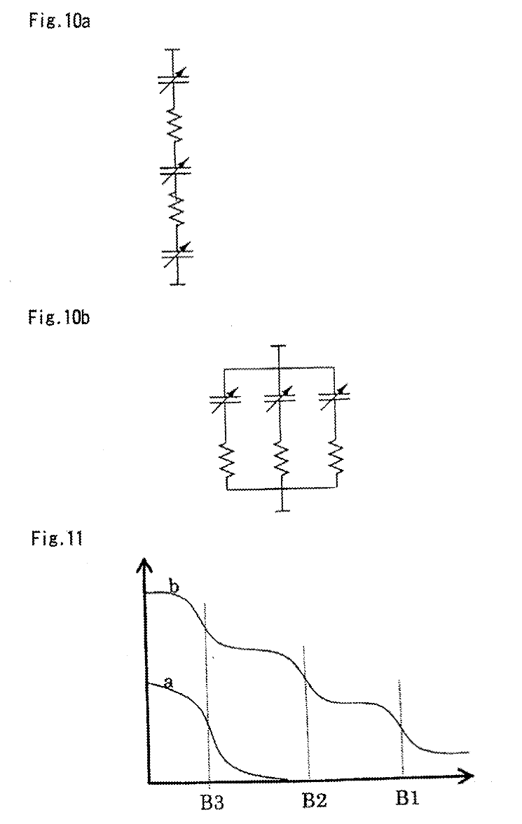

FIG. 10a is a diagram depicting an equivalent circuit where there is one kind of CNT layer, and FIG. 10b is a diagram depicting an equivalent circuit of the variable capacitance device shown in FIG. 9. In addition, in the equivalent circuit shown in FIG. 10a, all the variable capacitances have the same threshold, whereas in the equivalent circuit shown in FIG. 10b, the individual variable capacitances have different thresholds. Moreover, FIG. 11 is a diagram depicting changes in the capacitance value where a bias is applied to the circuits shown in FIGS. 10a and 10b. Furthermore, curve a shown in FIG. 11 indicates changes in the capacitance value where there is one kind of CNT layer, and curve b shown in FIG. 11 indicates changes in the capacitance value where the CNT layer is formed in three different areas.

As shown in FIG. 11, in the case in which there is one kind of CNT, a single bias value appears for which the capacitance value changes greatly, whereas in the case in which three kinds of CNTs are distributed in three areas, three bias values (B1, B2, and B3) exist for which the capacitance value changes greatly, corresponding to the thresholds of the individual CNT layers. As a result, it is possible to change the capacitance value according to the bias value in a wide range. This means that the effect widens the application range of the variable capacitance device allowing the device to be applied to a wide variety of circuits.

### Fifth Embodiment

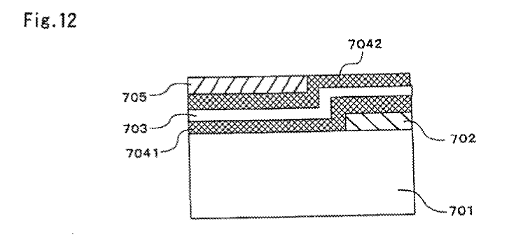

FIG. 12 is a cross sectional view depicting a variable capacitance device according to a fifth embodiment of the present invention.

As shown in FIG. 12, the variable capacitance device according to this embodiment includes polyimide substrate 701, first electrode 702, polyimide insulating film 703, first CNT layer 7041, second CNT layer 7042 that is a second nanomaterial layer, and second electrode 605.

Polyimide insulating film 703 exists between first CNT layer 7041 and second CNT layer 7042, and a capacitance is formed therebetween. In addition, first electrode 702 and second electrode 704 are respectively connected to first. CNT layer 7041 and second CNT layer 7042. Like this configuration, a capacitance is formed between the CNT layers, so that it is possible to increase the value of changes in the capacitance for the same bias variation.

According to the embodiments mentioned above, it is possible to obtain a device in which the capacitance is changed for the voltage to be applied depending on the physical properties of materials, using carbon nanotubes and the other materials for nanomaterials, as described in Non-Patent Document 1.

Moreover, because the nanomaterial layer is the mat layer having a random network of nanomaterials (for example, a plurality of carbon nanotubes), the nanomaterial layer is readily fabricated and has excellent matching with coating and printing processes. More particularly, employing metal nanoparticles also for forming the electrodes enables fabrication of the variable capacitance device using coating and printing processes throughout the entire fabrication processes.

In addition, because it is possible to fabricate, the above-mentioned variable capacitance devices according to the embodiments, by using coating and printing processes, lithography processes, high temperature processes, processes in a vacuum atmosphere, and other processes, which are necessary for conventional semiconductor fabrication, are eliminated to achieve large reductions in fabrication energy and in fabrication costs. Moreover, because it is possible to form the variable capacitance device to be operable at high frequencies on substrates having a variety of materials and shapes, such as a flexible plastic substrate, for example, the variable capacitance device contributes to reductions in size and thickness of information communication devices, portable terminals, or the like as well as to a dramatic improvement in the degree of freedom of design.

As discussed above, the present invention is described based on the preferred embodiments of the present invention. Here, particular specific examples are shown for explaining the present invention. These specific examples can be variously modified and altered within the scope not deviating from a wide range of teachings and scope of the present invention defined in the appended claims.

The present application claims the benefit of priority based on Japanese Patent Application No. 2008-282263, filed in Japan on Oct. 31, 2008, the entire disclosure of which is incorporated herein by reference.

### INDUSTRIAL APPLICABILITY

For exemplary utilizations of the present invention, such devices can be applied to a high frequency circuit on a plastic flexible substrate (a voltage-controlled oscillator, a phase-locked circuit, a frequency synthesizer, and a circuit of an antenna for frequency control or the like).

1. A variable capacitance device, comprising:
a nanomaterial layer made of a plurality of various kinds of nanomaterials having characteristics different from each other;
a first conductive layer electrically connected to at least a part of the nanomaterial layer; and
a second conductive layer facing the nanomaterial layer and the first conductive layer through an insulating film.

2. The variable capacitance device according to claim 1,
wherein the nanomaterial layer is a multi-layer film having the plurality of various kinds of nanomaterials formed in layers.

3. The variable capacitance device according to claim 2,
wherein the multi-layer film has a layer in contact with the insulating film and made of 100% semiconducting carbon nanotubes, and the multi-layer film has layers including metallic carbon nanotubes and having a percentage content of the metallic carbon nanotubes increasing as closer to the first conductive layer.

4. The variable capacitance device according to claim 1,
wherein the nanomaterial layer is formed to have the plurality of various kinds of nanomaterials in an arrangement on a same face.

5. The variable capacitance device according to claim 4,
wherein the nanomaterial layer formed in an arrangement is made of semiconducting carbon nanotubes having at least two kinds or more of band gaps.

6. The variable capacitance device according to claim 1,
wherein the nanomaterial is either a metallic carbon nanotube or a semiconducting carbon nanotube, or a mixture thereof.

7. The variable capacitance device according to claims 1,
wherein the first conductive layer and the second conductive layer are metal electrodes made of a metal nanoparticle.

8. The variable capacitance device according to claim 1,
wherein the first conductive layer entirely covers the nanomaterial layer.

9. The variable capacitance device according to claim 1, comprising a second nanomaterial layer provided to face the nanomaterial layer and the first conductive layer through the insulating film, the second nanomaterial layer being electrically connected to at least a part of the second conductive layer, the second nanomaterial layer being made of one kind or more of nanomaterials.

10. A method of fabricating a variable capacitance device, comprising:
a first ink applying step of applying ink containing a metal nanoparticle over a substrate;
a first conductive layer forming step of performing firing processing to precipitate a metal for forming a first conductive layer;
an insulating film forming step of forming an insulating film in at least a part of an area on the first conductive layer formed in the first conductive layer forming step;
a nanomaterial layer forming step of applying ink containing a nanomaterial over the insulating film formed in the insulating film forming step and forming a nanomaterial layer made of a plurality of various kinds of nanomaterials having characteristics different from each other;
a second ink applying step of applying ink containing a metal nanoparticle over at least a part of an area on the nanomaterial layer formed in the nanomaterial layer forming step; and
a second conductive layer forming step of performing firing processing to precipitate a metal for forming a second conductive layer electrically connected to the nanomaterial layer.

11. The method of fabricating a variable capacitance device according to claim 10,
wherein in the nanomaterial layer forming step, the plurality of various kinds of nanomaterials are formed in layers.

12. The method of fabricating a variable capacitance device according to claim 11,
wherein in the nanomaterial layer forming step, a layer made of 100% semiconducting carbon nanotubes is formed, the layer being contacted with the insulating film, and carbon nanotube layers including metallic carbon nanotubes being formed thereon, the carbon nanotube layers having a percentage content of the metallic carbon nanotubes that increases according to a forming order thereof.

13. The method of fabricating a variable capacitance device according to claim 10,
wherein in the nanomaterial layer forming step, the plurality of various kinds of nanomaterials are formed in an arrangement at a same face.

14. The method of fabricating a variable capacitance device according to claim 13,
wherein the nanomaterial layer formed in an arrangement is made of semiconducting carbon nanotubes having at least two or more kinds of band gaps.

15. The method of fabricating a variable capacitance device according to claim 10,
wherein the nanomaterial is either a metallic carbon nanotube or a semiconducting carbon nanotube, or a mixture thereof.

16. The method of fabricating a variable capacitance device according to claim 10,
wherein the first conductive layer and the second conductive layer are metal electrodes made of a metal nanoparticle.

17. The method of fabricating a variable capacitance device according to claim 10,
wherein in the second ink applying step, the ink containing the metal nanoparticle is applied to entirely cover the nanomaterial layer.
